(19) United States
(12) Patent Application Publication
(10) Pub. No.: US 2007/0260963 A1
(43) Pub. Date: Nov. 8, 2007

(54) ERROR CORRECTION SYSTEM AND RELATED METHOD THEREOF

(76) Inventor: Kuo-Lung Chien, Taipei City (TW)

Correspondence Address: NORTH AMERICA INTELLECTUAL PROPERTY CORPORATION, P.O. BOX 506, MERRIFIELD, VA, 22116, US

(21) Appl. No.: 11/737,750

(22) Filed: Apr. 20, 2007

Related U.S. Application Data
(60) Provisional application No. 60/745,281, filed on Apr. 21, 2006.

(51) Int. Cl. G11C 29/00

(52) U.S. Cl. 714/769

(57) ABSTRACT

Disclosed is an error correction system, comprising: a demodulator for receiving and demodulating raw data to generate an ECC block; an on the fly EDC check device for performing an EDC operation according to data of the ECC block from the demodulator to generate an EDC result; a data buffer for storing the ECC block and the EDC result; a syndrome generator for generating at least one syndrome according to a PI codeword and a PO codeword of the ECC block stored in the data buffer; an ECC decoder for performing an ECC operation according to the syndrome; and an EDC corrector for correcting the EDC result according to a result of the ECC operation received from the ECC decoder; wherein the syndrome comprises at least one of a PI syndrome and a PO syndrome.

### CROSS REFERENCE TO RELATED APPLICATIONS

This application claims the benefit of U.S. Provisional Application No. 60/745,281, filed 2006/04/21, which is included herein by reference.

### BACKGROUND

The present invention relates to an error correction system and a related method thereof, and more particularly relates to an error correction system for an optical disc drive and a related method thereof.

As the technique improves, the kinds of the optical discs and the data stored on which have grown, therefore an optical disc driver needs an error detection and correction mechanism to make sure that the read data is correct.

FIG. 1 is a block diagram illustrating a related art error correction system 100. As shown in FIG. 1, the error correction system 100 includes a data buffer 101, a demodulator 103, a syndrome generator 105, a syndrome memory 107, an ECC (error correction code) decoder 109, a linear EDC (error detection code) check device 111, an EDC memory 113 and an EDC corrector 115. In this example, the ECC block stored in the data buffer 101 is read out for performing a PI/PO syndrome calculation and linear EDC when the amount of data stored in the data buffer 101 is sufficient for decoding. Simultaneously, a PI ECC operation is performed to correct the error data stored in the data buffer 101 if any error has been found, and the syndrome stored in the syndrome memory 107 is updated. Moreover, the ECC operation of the next direction (PO in this example) is performed via directly reading the syndrome stored in the syndrome memory 107 instead of computing syndromes from the data stored in the data buffer 101. However, such structure lacks a PI direction ECC, therefore it has worse performance. Also, such structure lacks a mechanism to overcome frame sync shift problem.

Besides above-mentioned related art and disadvantages thereof, other related arts are invented and theses related arts still have other disadvantages due to different factors, which can be summarized as below. If the system only has on the fly PO syndrome calculation, it cannot overcome the frame sync shift. Also, if the system has on the fly EDC mechanism, it cannot over come frame sync shift, either. If the system has final EDC mechanism, it also has worst performance. If the system has on the fly syndrome calculation, it has higher cost. If the system has no memory device between the demodulator and the on the fly PI ECC device, the system cannot overcome frame sync shift problem caused by sync data lost and has poor bandwidth caused by correction cycle on data buffer. The “on the fly” means that the data is processed before entering data buffer. For example, on the fly PI ECC means the data from the modulator is performed PI ECC before entering data buffer.

### SUMMARY OF THE INVENTION

Therefore, one objective of the present invention is to provide an error correction system maintaining the above-mentioned advantages while avoiding the above-mentioned disadvantages.

One embodiment of the present invention discloses an error correction system, comprising: a demodulator for receiving and demodulating raw data to generate an ECC block; an on the fly EDC check device for performing an EDC operation according to data of the ECC block from the demodulator to generate an EDC result; a data buffer for storing the ECC block and the EDC result; a syndrome generator for generating at least one syndrome according to a PI codeword and a PO codeword of the ECC block stored in the data buffer; an ECC decoder for performing an ECC operation according to the syndrome; and an EDC corrector for correcting the EDC result according to a result of the ECC operation received from the ECC decoder; wherein the syndrome comprises at least one of a PI syndrome and a PO syndrome.

A method corresponding to this system is also disclosed, which comprises: (a) receiving and demodulating raw data to generate an ECC block; (b) performing an EDC operation according to data of the ECC block to generate an EDC result; (c) storing the ECC block and the EDC result; (d) generating at least one syndrome according to a PI codeword and a PO codeword of the stored ECC block; (e) performing an ECC operation according to the syndrome; and (f) correcting the EDC result according to a result of the ECC operation; wherein the syndrome comprises at least one of a PI syndrome and a PO syndrome.

Another embodiment of the present invention discloses an error correction system, comprising: a demodulator, for receiving and demodulating raw data to generate an ECC block; an on the fly EDC check device for performing an EDC operation according to data of the ECC block from the demodulator to generate an EDC result; a data buffer for storing the ECC block and the EDC result; an on the fly PI ECC decoder for performing a PI ECC operation on the ECC block from the demodulator, thereby correcting the ECC block in the data buffer and amending the EDC result according to a result of the PI ECC operation; a memory device for buffering the ECC block from the data buffer; a PO syndrome generator for generating a PO syndrome according to a PO codeword of the ECC block stored in the memory device; a PI syndrome generator for generating a PI syndrome according to the ECC block stored in the memory device; an ECC decoder for performing an ECC operation according to at least one of the PI syndrome and the PO syndrome; and an EDC corrector for correcting the EDC result according to a result of the ECC operation.

A method corresponding to this system is also disclosed, which comprises: (a) receiving and demodulating raw data to generate an ECC block; (b) performing an EDC operation according to data of the ECC block to generate an EDC result; (c) storing the ECC block and the EDC result; (d) performing a PI ECC operation on the ECC block, thereby correcting the ECC block and amending the EDC result according to a result of the PI ECC operation; (e) storing a part of the stored ECC block; (f) generating a PO syndrome according to a PO codeword of the ECC block buffered; (g) generating a PI syndrome according to the ECC block; (h) performing an ECC operation according to at least one of the PI syndrome and the PO syndrome; and (i) correcting the EDC result according to a errata result of the ECC operation.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram illustrating a related art error correction system.

FIG. 2 is a block diagram illustrating an error correction system according to a first embodiment of the present invention.

FIG. 3 is a block diagram illustrating an error correction system according to a second embodiment of the present invention.

FIG. 4 is a block diagram illustrating an error correction system according to a third embodiment of the present invention.

FIG. 5 is a block diagram illustrating an error correction system according to a fourth embodiment of the present invention.

FIG. 6 is a block diagram illustrating an error correction system according to a fifth embodiment of the present invention.

FIG. 7 is a block diagram illustrating an error correction system according to a sixth embodiment of the present invention.

FIG. 8 is a block diagram illustrating an error correction system according to a seventh embodiment of the present invention.

FIG. 9 is a block diagram illustrating an error correction system according to an eighth embodiment of the present invention.

FIG. 10 is a block diagram illustrating an error correction system according to a ninth embodiment of the present invention.

FIG. 11 is a block diagram illustrating an error correction system according to a tenth embodiment of the present invention.

FIG. 12 is a block diagram illustrating an error correction system according to an eleventh embodiment of the present invention.

FIG. 13 is a block diagram illustrating an error correction system according to a twelfth embodiment of the present invention.

FIG. 14 is a block diagram illustrating an error correction system according to a thirteenth embodiment of the present invention.

FIG. 15 is a block diagram illustrating an error correction system according to a fourteenth embodiment of the present invention.

FIG. 16 is a block diagram illustrating an error correction system according to a fifteenth embodiment of the present invention.

FIG. 17 is a block diagram illustrating an error correction system according to a sixteenth embodiment of the present invention.

FIG. 18 is a block diagram illustrating an error correction system according to a seventeenth embodiment of the present invention.

FIG. 19 is a block diagram illustrating an error correction system according to an eighteenth embodiment of the present invention.

FIG. 20 is a block diagram illustrating an error correction system according to an eighteenth embodiment of the present invention.

FIG. 21 illustrates an error correction method corresponding to the error correction system 1100 shown in FIG. 2.

FIG. 22 illustrates an error correction method corresponding to the error correction system 1400 shown in FIG. 5.

FIG. 23 illustrates a flow chart illustrating an error correction method corresponding to the error correction system 1500 shown in FIG. 6.

FIG. 24 illustrates a flow chart illustrating an error correction method corresponding to the error correction system 1700 shown in FIG. 8.

FIG. 25 illustrates a flow chart illustrating an error correction method corresponding to the error correction system 1800 and 1900 shown in FIG. 9˜FIG. 20.

### DETAILED DESCRIPTION

Certain terms are used throughout the description and following claims to refer to particular components. As one skilled in the art will appreciate, electronic equipment manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

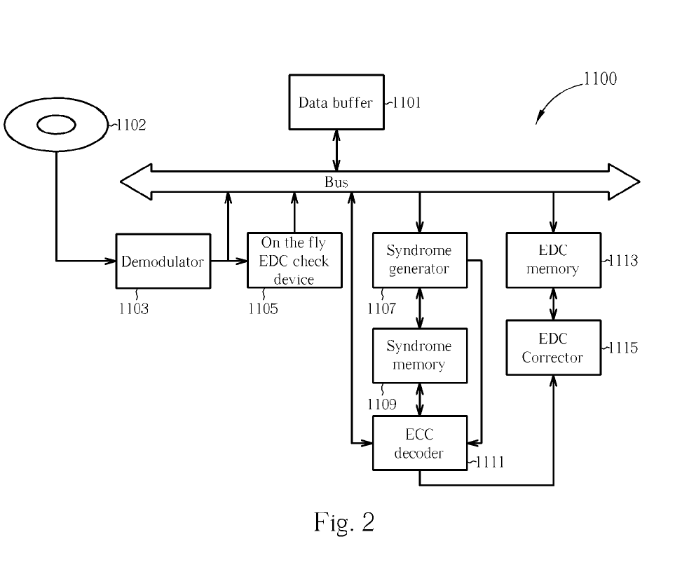

FIG. 2 is a block diagram illustrating an error correction system 1100 according to a first embodiment of the present invention. As shown in FIG. 2, the error correction system 1100 comprises a data buffer 1101, a demodulator 1103, an on the fly EDC check device 1105 (i.e. on the fly means the data is processed before entering the data buffer), a syndrome generator 1107, a syndrome memory 1109, an ECC decoder 1111, an EDC memory 1113 and an EDC corrector 1115. The demodulator 1103 is used for receiving and demodulating raw data from the optical disc 1102 to generate an ECC block that comprises data, PI parity, and PO parity. The on the fly EDC check device 1105 is used for performing an EDC operation according to the data of the ECC block from the demodulator 1105 to generate an EDC result. The data buffer 1101 is used for storing the ECC block and the EDC result. The syndrome generator 1107 is used for generating PI syndrome and PO syndrome according to the PI codeword and the PO codeword stored in the data buffer 1101. The syndrome memory 1109 is used for storing the PI syndrome and the PO syndrome. The ECC decoder 1111 is used for performing an error correction on the data of the ECC block stored in the data buffer 1101 according to the PI syndrome or the PO syndrome stored in the syndrome memory 1109 and for correcting the PI syndrome or the PO syndrome in the syndrome memory 1109 according to the errata result. The EDC memory 1113 is used for buffering the EDC result. The EDC corrector 1115 is used for correcting the EDC result according to the errata result received from the ECC decoder 1111.

In this case, the next direction ECC operation (that is, error correction operation) is performed by directly reading syndrome from the syndrome memory 1109. Additionally, the syndrome memory 1109 and the EDC memory 1113 can be integrated to the data buffer 1101, and this also falls within the scope of the present invention.

In short, the operation of the error correction system 1100 can be described as follows: The data demodulated by the demodulator 1103 is transmitted to the on the fly EDC check device 1105 and the data buffer 1101, and the EDC result is stored in the data buffer 1101. Then the following operations are performed if enough data for decoding is buffered in the data buffer 1101: The EDC result in the data buffer 1101 is read and stored in the EDC memory 1113. The ECC blocks comprising data, PI, PO parity in the data buffer 1101 are read, PI, PO syndromes are generated according to the PI, PO codeword and stored in the syndrome memory 1109, and then a ECC operation with a first direction is performed. Error data in the data buffer 1101 is corrected if any error is found, a corresponding syndrome is updated via a syndrome correction circuit (not illustrated) in the ECC decoder 1111 simultaneously, and the EDC result in the EDC memory 1113 is updated via the EDC corrector 1115 simultaneously. Next, an ECC operation of the next direction is performed by directly reading a syndrome from the syndrome memory 1109 instead of accessing the ECC block in the data buffer 1101 to re-compute the syndrome. ECC operations of two directions continue repeatedly and alternately until the repeating numbers reach a predetermined value or no error data exists.

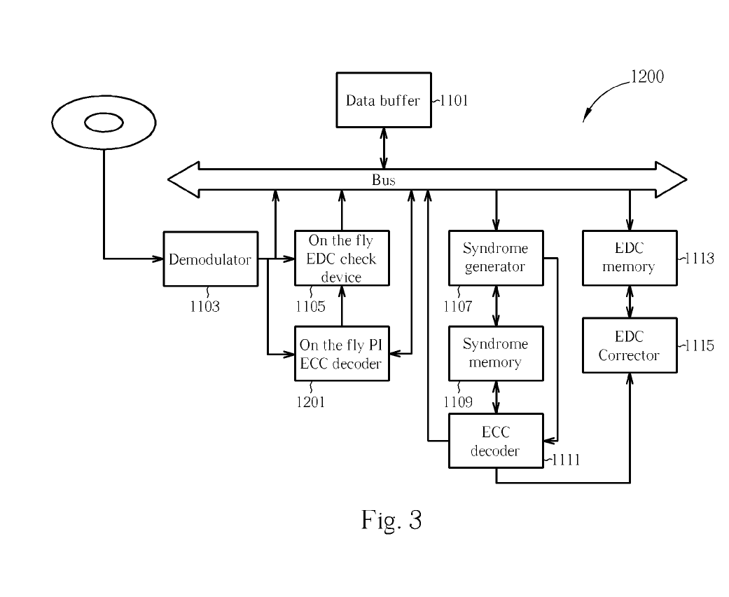

FIG. 3 is a block diagram illustrating an error correction system 1200 according to a second embodiment of the present invention. Compared with the error correction system 1100, the error correction system 1200 further comprises an on the fly PI ECC decoder 1201 (i.e. on the fly means the data is processed before entering the data buffer), is used for performing a PI ECC operation on the data directly from the demodulator 1103 and for amending the EDC result stored in the data buffer 1101 according to the errata result. Therefore, the operation of the error correction system 1200 is different from the error correction system 1100. For the error correction system 1200, the data demodulated by the demodulator 1103 is further transmitted tithe on the fly PI ECC decoder 1201 besides above-mentioned devices, and the EDC result is stored in the data buffer 1101. The on the fly PI ECC decoder 1201 performs an PI ECC operation on the data stored in the data buffer 1101, and the on the fly EDC check device 1105 performs EDC operation on the main data directly from the demodulator 1103. The operations performed when enough data buffered in the data buffer 1101 is similar with the operations shown in FIG. 2, and can be easily presumed by above-mentioned description, thus it is omitted for brevity.

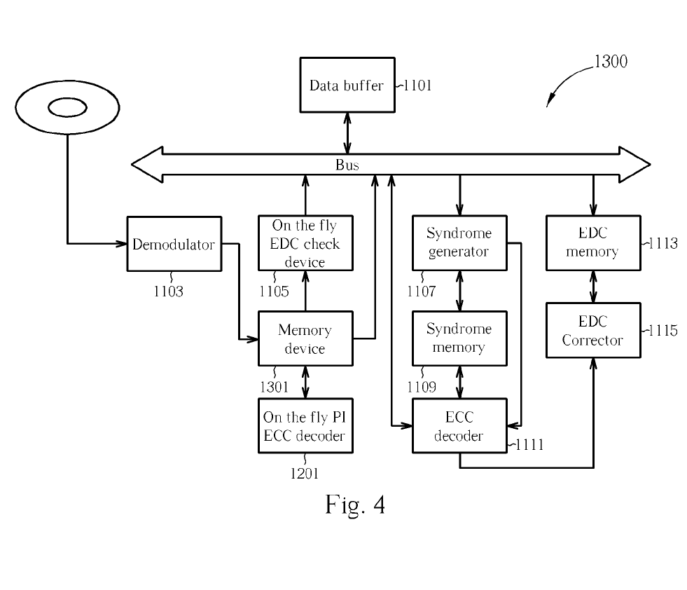

FIG. 4 is a block diagram illustrating an error correction system 1300 according to a third embodiment of the present invention. Compared with the error correction system 1200, the error correction system 1300 further includes a memory device 1301 coupled between the on the fly EDC check device 1105 and the on the fly PI ECC decoder 1201. Therefore, few rows of the demodulated data from the demodulator 1103 are temporarily buffered in the memory device 1301. The on the fly PI ECC decoder 1201 is used for performing a PI ECC operation on the ECC block stored in the memory device 1301. Also, the on the fly EDC check device 1105 is further coupled to the memory device 1301 for performing the EDC operation on the main data in the ECC block to generate the EDC result. Other operations of the error correction system 1300 are similar with error correction system 1200, and therefore omitted for brevity.

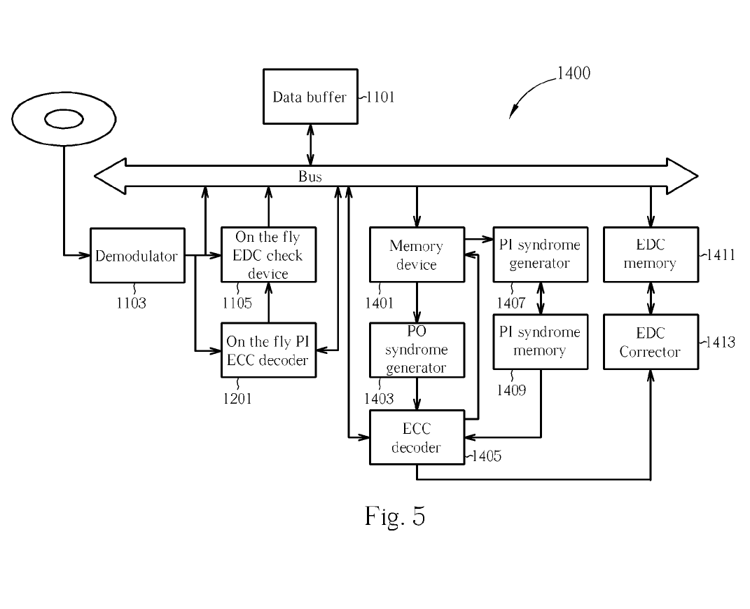

FIG. 5 is a block diagram illustrating an error correction system 1400 according to a fourth embodiment of the present invention. Similar to the error correction system 1200, the error correction system 1400 includes a data buffer 1101, a demodulator 1103, an on the fly EDC check device 1105 and an on the fly PI ECC decoder 1201. However, the error correction system 1400 further includes a memory device 1401, a PO syndrome generator 1403, an ECC decoder 1405, a PI syndrome generator 1407, a PI syndrome memory 1409, an EDC memory 1411, and an EDC corrector 1413. The demodulator 1103 is used for receiving and demodulating raw data to generate a ECC block. The on the fly EDC check device 1105 is used for performing an EDC operation on the main data of the ECC block to generate an EDC result. The data buffer 1101 is used for storing the ECC block and the EDC result. The on the fly PI ECC decoder 1201 is used for performing an PI ECC operation on the data of the ECC block directly from the demodulator 1103 and for amending the EDC result stored in the data buffer 1101 according to the errata result from the PI ECC operation. The memory device 1401 is used for temporally buffering few columns of the ECC block from the data buffer 1101. The PO syndrome generator 1403 is used for generating a PO syndrome according to PO codeword of the ECC block stored in the memory device 1401. The PI syndrome memory 1409 is used for storing partial PI syndrome from the PI syndrome generator 1407. The ECC decoder 1405 is used for performing error correction according to the PI syndrome or the PO syndrome. The PI syndrome generator 1407 is used for generating the PI syndrome according to the ECC block stored in the memory device 1401. The EDC memory 1411 is used for buffering the EDC result. The EDC corrector 1413 is used for correcting the EDC result according to the errata result received from the ECC decoder 1405.

In short, the operation of the error correction system 1400 can be described as follows: The demodulated data from the demodulator 1103 is transmitted to the on the fly EDC check device 1105, the on the fly PI ECC decoder 1201 and the data buffer 1101. Then the on the fly PI ECC decoder 1201 performs a PI ECC operation on the ECC block directly from the demodulator 1103, and the on the fly EDC check device 1105 calculates the EDC result, stores it in the data buffer 1101, and updates the EDC result according to the on the fly PI ECC errata result. Then the following operations are performed if enough data for decoding is buffered to the data buffer 1101. The EDC result is read from the data buffer 1101 and stored in the EDC memory 1411. Few columns of the ECC block are read and temporarily stored in the memory device 1401, and a PO ECC operation is performed on the column data in the memory device 1401 to generate errata result. Next, the error data in the data buffer 1101 is corrected and the EDC result in the EDC memory 1411 is updated by errata result via the EDC corrector 1413. After that, the PI syndrome generator 1407 reads the column corrected data from the memory device 1401 to generate a PI syndrome, and the PI syndrome is stored in the PI syndrome memory 1409. After all the data are processed by the PO ECC operation, the PI syndrome is read from the PI syndrome memory 1409 and the PI ECC operation is performed.

Next, the error data in the memory device 1401 and the data buffer 1101 is corrected and the EDC result in the EDC memory is updated correspondingly via the EDC corrector 1413. PI and PO ECC operations continue repeatedly and alternately until the repeating numbers reach a predetermined value or no error data exists. Furthermore, the error correction system 1400 can comprise a memory device between the on the fly EDC check device 1105 and the on the fly PI ECC decoder 1201.

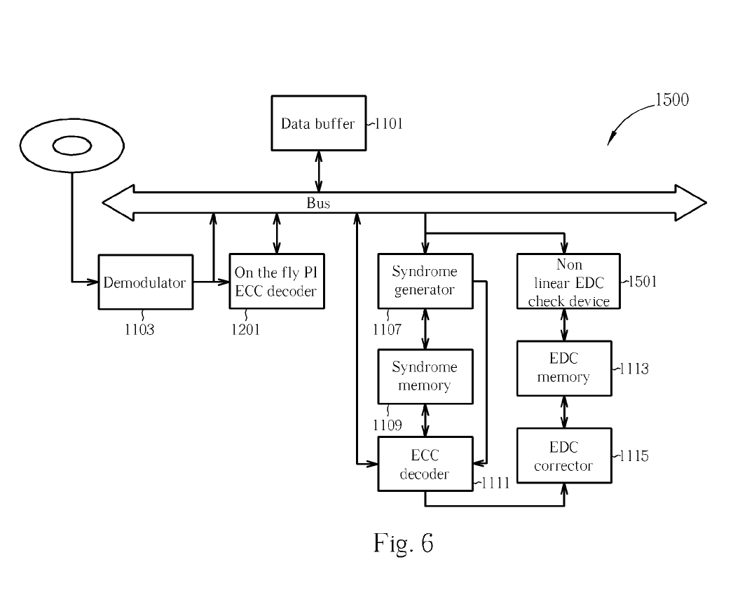

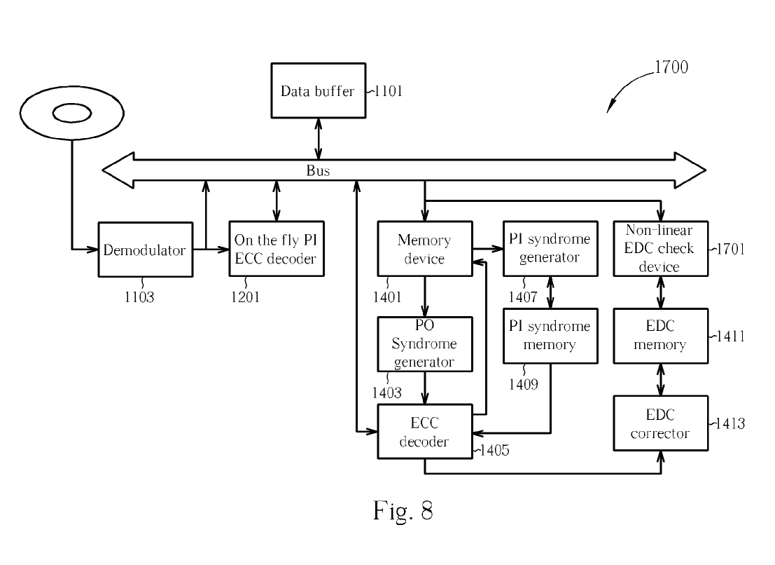

The embodiments shown in FIG. 6˜FIG. 8 are similar to those shown in FIG. 3˜FIG. 5, the difference between them being that the EDC check devices in FIG. 3˜FIG. 5 are on the fly EDC check devices, that is, the EDC check devices are located before the data buffer, but the EDC check devices in FIG. 6˜FIG. 8 are located behind the data buffer. Therefore, the operations of the error correction systems in FIG. 3˜FIG. 5 and FIG. 6˜FIG. 8 have some difference.

FIG. 6 is a block diagram illustrating an error correction system 1500 according to a fifth embodiment of the present invention. Please refer to both FIG. 3 and FIG. 6. The structures of FIG. 3 and FIG. 6 are similar but the error correction system 1500 has an non linear EDC check device 1501 located behind the data buffer 1101 instead of the on the fly EDC check device 1105 located before the data buffer 1101, thus the error correction systems 1200 and 1500 have some different operations.

For the error correction system 1500, the data demodulated by the demodulator 1103 is transmitted to the data buffer 1101 and the on the fly PI ECC decoder 1201. Then the on the fly PI ECC decoder 1201 performs a PI ECC operation on the data directly from the demodulator 1103. The following operations are then performed if enough data for decoding is buffered in the data buffer 1101: The ECC blocks comprising data, PI, PO codeword in the data buffer 1101 are read, simultaneously PI, PO syndromes are generated according to the PI, PO codeword and stored in the syndrome memory 1109. An ECC operation with a first direction is performed. Simultaneously with ECC blocks are read from the data buffer 1101, the non linear EDC check device 1501 performs a non-linear EDC operation on the ECC block to generate an EDC result, and the EDC result is stored in the EDC memory 1113. Simultaneously, error data in the data buffer 1101 is corrected if any error is found, a corresponding syndrome is updated via a syndrome correction circuit (not illustrated) in the ECC decoder 1111, and the EDC result in the EDC memory 1113 is updated via the EDC corrector 1115. Next, an ECC operation of the next direction is performed by directly reading a syndrome from the syndrome memory 1109 instead of accessing the data in the data buffer 1101 to re-compute the syndrome. ECC operations with two directions continue repeatedly and alternately until the repeating numbers reach a predetermined value or no error data exists.

The detail description of the linear and non-linear EDC operation can be reference to U.S. patent with application Ser. No. 11/531,280, which is applied by the same assignee and has the same inventors.

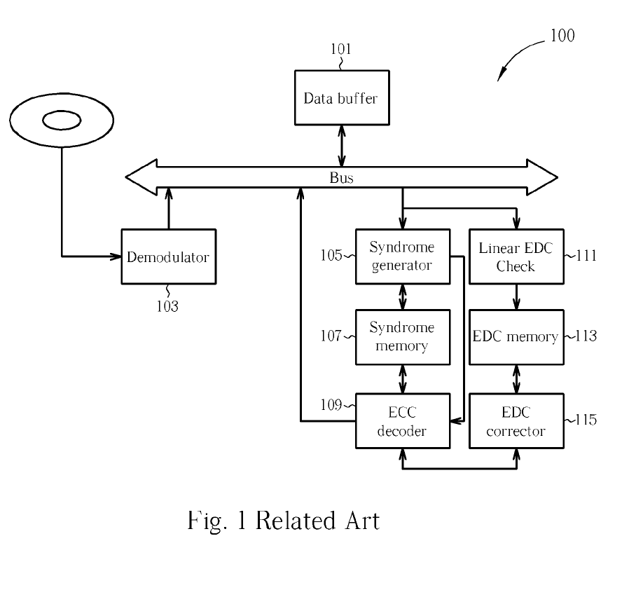

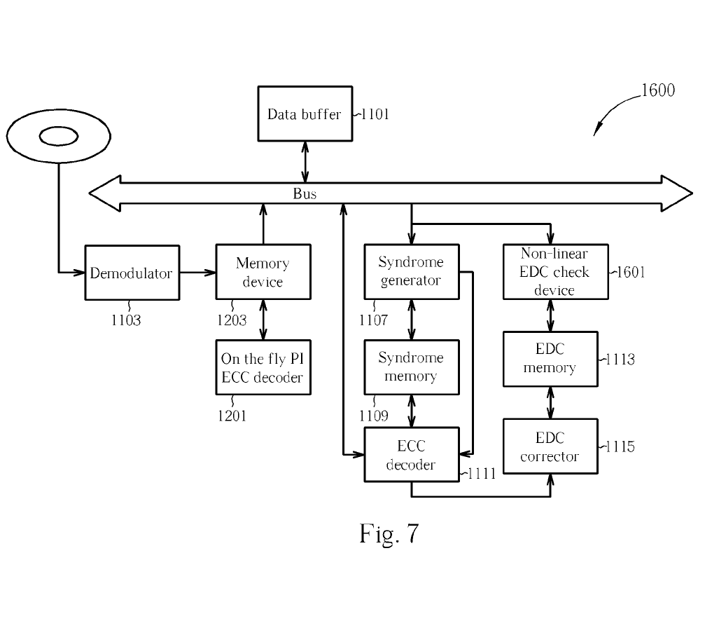

FIG. 7 is a block diagram illustrating an error correction system 1600 according to a sixth embodiment of the present invention. The structures of FIG. 4 and FIG. 7 are similar but the error correction system 1600 has a non-linear EDC check device 1601 located behind the data buffer 1101 instead of the on the fly EDC check device 1105 located before the data buffer 1101, thus the error correction system 1300 and 1600 have some different operations. The demodulated data from the demodulator 1103 is stored in the memory device 1203. The on the fly PI ECC decoder 1201 is used for performing a PI ECC operation on the ECC block stored in the memory device 1203 to generate a corrected ECC block, wherein the memory device 1203 is for temporarily buffering few rows of the ECC block. Other operations of the error correction system 1600 shown in FIG. 7 are similar with error correction system 1500 shown in FIG. 6, and are thus omitted for brevity. Comparing with the related art shown in FIG. 1, the error correction system 1600 shown in FIG. 7 further includes an on the fly PI ECC decoder 1201 and memory device 1203. Also, the EDC check device of the error correction system 1600 shown in FIG. 7 is the non-linear EDC check device 1601 instead of a linear EDC check device. Therefore, the error correction system 1600 has a better performance due to the on the fly PI ECC decoder 1201, and can decrease bandwidth due to the memory device 1203. Also, the utilization of the non-linear EDC check device 1601 can help over come frame sync shift problem.

FIG. 8 is a block diagram illustrating an error correction system 1700 according to a seventh embodiment of the present invention. Please refer to FIG. 5 and FIG. 8, the structures of FIG. 5 and FIG. 8 are similar but the error correction system 1700 has an non linear EDC check device 1701 located behind the data buffer 1101 instead of the on the fly EDC check device 1105 located before the data buffer 1101, thus the error correction system 1400 and 1700 have some different operations.

For the error correction system 1700, the demodulated data from the demodulator 1103 is transmitted to the on the fly PI ECC decoder 1201 and the data buffer 1101. Then the on the fly PI ECC decoder 1201 performs a PI ECC operation on the ECC block from demodulator 1103. Next the following operations are performed if enough data for decoding is buffered in the data buffer 1101: The ECC block is read from the data buffer 1101 and the non linear EDC check device 1701 performs a non linear EDC operation on the ECC block to generate an EDC result, which is stored in the EDC memory 1411.

Few columns of the ECC block in the data buffer 1101 is read and temporarily buffered in the memory device 1401, and a PO ECC operation is performed on the column data in the memory device 1401 to generate errata result. Next, the EDC result in the EDC memory 1411 is updated by errata result via the EDC corrector 1413. After that, the PI syndrome generator 1407 reads the column corrected data from the memory device 1401 to generate a PI syndrome, and the PI syndrome is stored in the PI syndrome memory 1409. After all the column data are processed by the PO ECC operation, the PI syndrome is read from the PI syndrome memory 1409 and the PI ECC operation is performed. Next, the error data in the memory device 1401 and the data buffer 1101 is corrected and the EDC result in the EDC memory 1411 is updated correspondingly via the EDC corrector 1413. PI and PO ECC operations continue repeatedly and alternately until the repeating numbers reach a predetermined value or no error data exists.

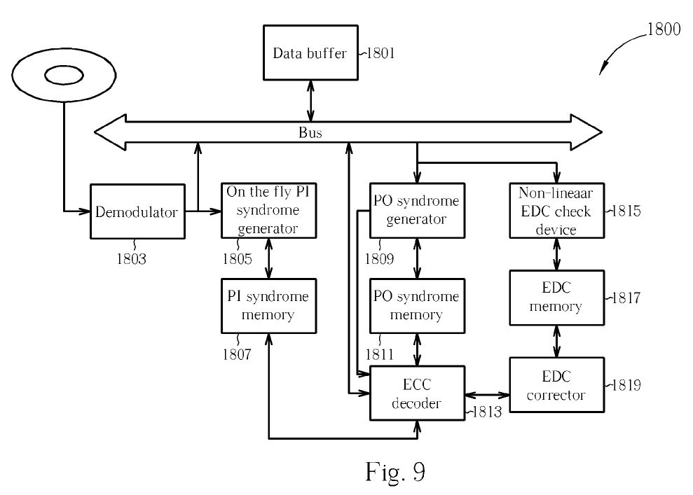

FIGS. 9-12 disclose other embodiments according to the present invention, which also have non-linear EDC check devices behind the data buffer. FIG. 9 is a block diagram illustrating an error correction system 1800 according to an eighth embodiment of the present invention. As shown in FIG. 9, the error correction system 1800 comprises a data buffer 1801, a demodulator 1803, a on the fly PI syndrome generator 1805, a PI syndrome memory 1807, a PO syndrome generator 1809, a PO syndrome memory 1811, an ECC decoder 1813, a non linear EDC check device 1815, an EDC memory 1817, and an EDC corrector 1819. The demodulator 1803 is used for receiving and demodulating raw data from an optical disc to generate an ECC block that comprises data, PI parity, and PO parity. The data buffer 1801 is used for storing the ECC block. The on the fly PI syndrome generator 1805 is used for generating a PI syndrome according to the PI codeword of the ECC block. The PI syndrome memory 1807 is used for storing the PI syndrome. The PO syndrome generator 1809 is used for generating PO syndromes according to the PO codeword of the ECC block buffered in the data buffer 1801. The non linear EDC check device 1815 is used for performing a non-linear EDC operation on the main data of the ECC block to generate an EDC result.

The PO syndrome memory 1811 is used for storing the PO syndrome. The ECC decoder 1813 is used for performing an ECC operation on the data of the ECC block buffered in the data buffer 1801 according to the PI syndrome buffered in the PI syndrome memory 1807 to generate a PI errata result and for performing a PO ECC operation on the data of the ECC block buffered in the data buffer 1801 according to the PO syndrome buffered in the PO syndrome memory 1811 to generate a PO errata result. The EDC memory 1817 is used for buffering the EDC result. The EDC corrector 1819 is used for correcting the EDC result according to the PI errata result or the PO errata result received from the ECC decoder 1813.

In short, the operation of the error correction system 1800 can be described as follows: The demodulated data from the demodulator 1803 is transmitted to the on the fly PI syndrome generator 1805 and the data buffer 1801, and the PI syndrome is stored in the PI syndrome memory 1807. The following operations are performed if enough data for decoding is buffered in the data buffer 1801: The ECC decoder 1813 performs a PI ECC operation on the data stored in the data buffer 1801 according to the PI syndrome stored in the PI syndrome memory 1807, a syndrome correction circuit (not illustrated) in the ECC decoder 1813 updates the syndrome in the syndrome memory 1807 correspondingly simultaneously, and the EDC corrector 1819 updates the EDC result in the EDC memory 1817 correspondingly and simultaneously.

Moreover, the ECC block is read from the data buffer 1801, and the PO syndrome generator 1809 generates a PO syndrome, which is stored in the PO syndrome memory 1811, and the ECC decoder 1813 and EDC check device 1815 perform a PO ECC operation according to the syndrome result and a non-linear EDC operation on the main data stored in the data buffer 1801, wherein the result of the non-linear EDC operation is stored in the EDC memory 1817. The ECC decoder 1813 corrects error data in the data buffer 1801, the syndrome correction circuit in the ECC decoder 1813 updates the syndrome in the syndrome memory correspondingly and simultaneously, and the EDC corrector 1819 corrects the EDC result in the EDC memory 1817 correspondingly and simultaneously.

The ECC operation of the next direction is performed via directly reading the syndrome stored in the syndrome memory 1811 instead of computing syndromes from the data stored in the data buffer 1801. PI and PO ECC operations continue repeatedly and alternately until the repeating numbers reach a predetermined value or no error data exists.

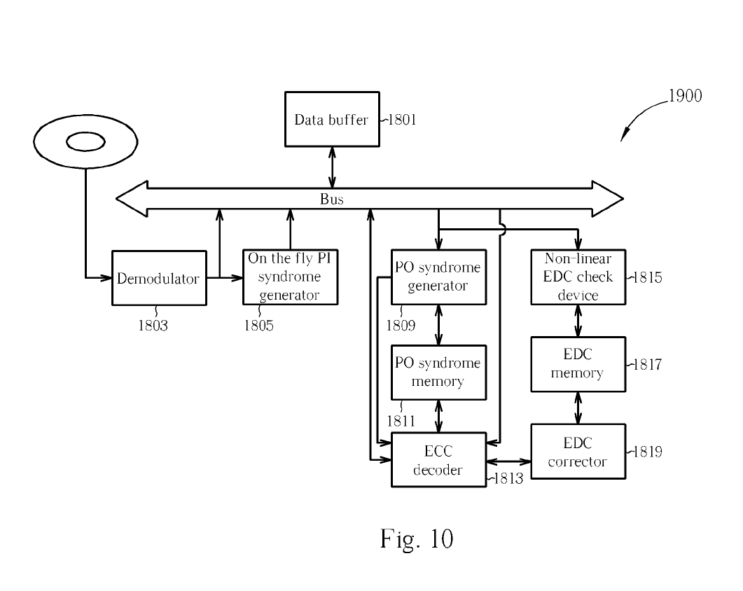

The PI syndrome memory 1807 can be integrated to the data buffer 1801, as shown in FIG. 10. FIG. 10 is a block diagram illustrating an error correction system 1900 according to a ninth embodiment of the present invention. As shown in FIG. 10, the error correction system 1900 has the same elements as error correction system 1800 except for the PI syndrome memory 1807, and the connection between each element of the error correction system 1900 is also different from the error correction system 1800.

The operation of the error correction system 1900 can be summarized as follows. The demodulated data from the demodulator 1803 is transmitted to the on the fly PI syndrome generator 1805 and the data buffer 1801, and the PI syndrome is stored in the data buffer 1801. Next the following operations are performed if enough data for decoding is buffered in the data buffer 1801: The ECC decoder 1813 performs a PI ECC operation according to the PI syndrome stored in the data buffer 1801 and corrects data in the data buffer 1801, a syndrome correction circuit (not illustrated) in the ECC decoder 1813 updates the syndrome in the data buffer 1801 correspondingly simultaneously, and the EDC corrector 1819 updates the EDC result in the EDC memory 1817 correspondingly and simultaneously. Next, the ECC block is read from the data buffer 1801, and the PO syndrome generator 1809 generates a PO syndrome, which is stored in the PO syndrome memory 1811. The PO ECC operation is performed after the syndrome generator 1809 computes PO syndrome. The ECC decoder 1813 and the non-linear EDC check device 1815 perform a PO ECC operation according to PO syndrome result and a non-linear EDC operation on the data stored in the data buffer 1801 respectively, wherein the result of the non-linear EDC operation is stored in the EDC memory 1817. The ECC decoder 1813 corrects error data in the data buffer, the syndrome correction circuit in the ECC decoder 1813 updates the PO syndrome in the PO syndrome memory 1811 and the PI syndrome in the data buffer 1801 correspondingly, and the EDC corrector 1819 corrects the EDC result in the EDC memory 1817 correspondingly. Next, the ECC operation of the next direction is performed via directly reading the syndrome stored in the PO syndrome memory 1811 or the data buffer 1801 instead of computing a syndrome from the data stored in the data buffer 1801. PI and PO ECC operations continue repeatedly and alternately until the repeating numbers reach a predetermined value or no error data exists.

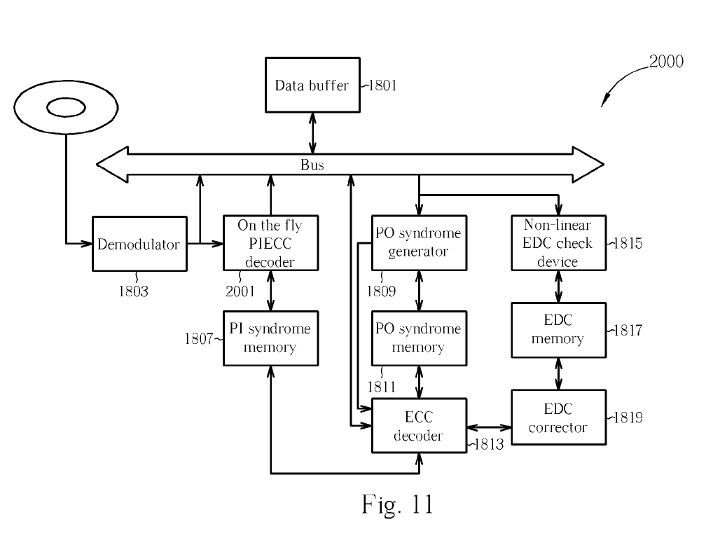

The on the fly PI syndrome generator 1805 can be integrated to an on the fly PI ECC decoder, as shown in FIG. 11. FIG. 11 is a block diagram illustrating an error correction system 2000 according to a tenth embodiment of the present invention. In this embodiment, the demodulated data from the demodulator 1803 is transmitted to the on the fly PI ECC decoder 2001 and the data buffer 1801, and the syndrome generator in the on the fly PI ECC decoder 2001 generates a PI syndrome to be stored in the PI syndrome memory 1807. The on the fly PI ECC decoder 2001 directly performs a PI ECC operation on the data from the demodulator 1803, and a syndrome correction circuit in the on the fly PI ECC decoder 2001 updates the PI syndrome in the PI syndrome memory 1807 correspondingly and simultaneously.

The following operations are performed if enough data for decoding is buffered in the data buffer 1801. The ECC block is read from the data buffer 1801, the PO syndrome generator 1809 generates a PO syndrome, which is stored in the PO syndrome memory 1811, and the ECC decoder 1813 and the non-linear EDC check device 1815 perform an ECC operation according to syndrome result with one direction and a non-linear EDC operation on the data stored in the data buffer 1801, wherein the result of the non-linear EDC operation is stored in the EDC memory 1817. After that, the ECC decoder 1813 corrects error data in the data buffer 1801, the syndrome correction circuit in the ECC decoder 1813 updates the PI and PO syndrome in the PI syndrome memory 1807 and the PO syndrome memory 1811 correspondingly, and the EDC corrector 1819 corrects the EDC result in the EDC memory 1817 correspondingly. Next, the ECC operation of the next direction is performed via directly reading the syndrome stored in the syndrome memory 1807 instead of computing a syndrome from the data stored in the data buffer 1801. PI and PO ECC operations continue repeatedly and alternately until the repeating numbers reach a predetermined value or no error data exists.

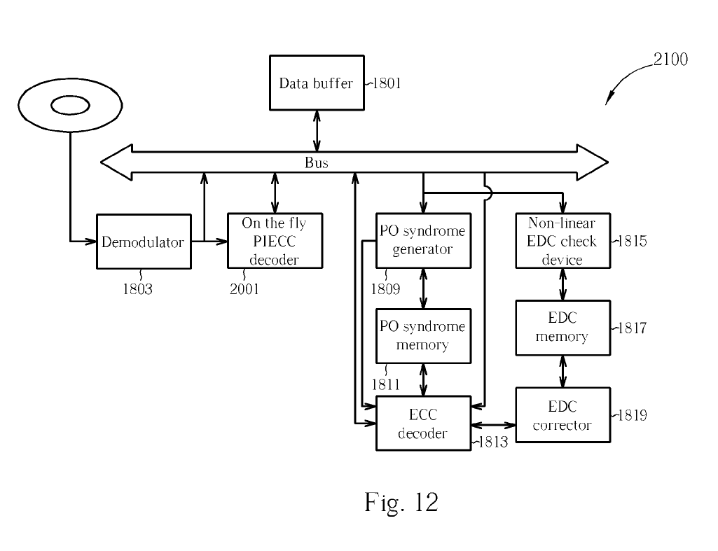

The PI syndrome memory 1807 shown in FIG. 11 can be integrated to the data buffer 1801, as shown in FIG. 12. FIG. 12 is a block diagram illustrating an error correction system 2100 according to an eleventh embodiment of the present invention. In this embodiment, the PI syndrome is stored in the data buffer 1801 instead of the PI syndrome memory 2001. Other operations are similar to operations of the error correction system 2000, and are thus omitted for brevity.

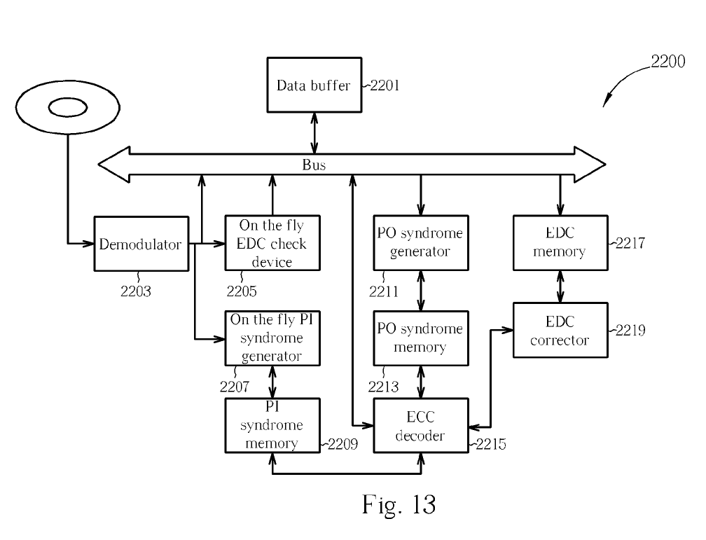

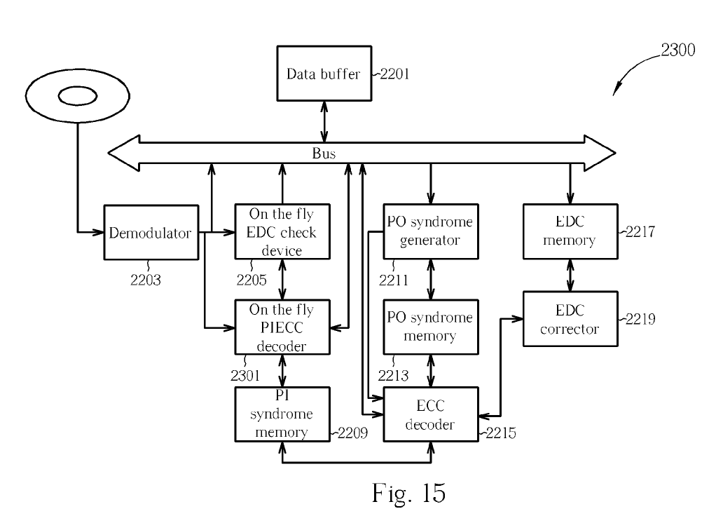

FIG. 13˜FIG. 15 are block diagrams illustrating other embodiments of the present invention; these embodiments include an on the fly EDC check device and a syndrome generator or an on the fly ECC device located before a data buffer, and have the same elements located behind the data buffer.

FIG. 13 is a block diagram illustrating an error correction system 2200 according to a twelfth embodiment of the present invention. As shown in FIG. 13, the error correction system 2200 comprises a data buffer 2201, a demodulator 2203, an on the fly EDC check device 2205, a on the fly PI syndrome generator 2207, a PI syndrome memory 2209, a PO syndrome generator 2211, a PO syndrome memory 2213, an ECC decoder 2215, an EDC memory 2217, and an EDC corrector 2219. The demodulator 2203 is used for receiving and demodulating raw data to generate an ECC block that comprises data, PI parity, and Po parity. The on the fly EDC check device 2205 is used for performing an EDC operation on the main data of the ECC block from the demodulator 2203 to generate an EDC result. The data buffer 2203 is used for storing the ECC block and the EDC result. The on the fly PI syndrome generator 2207 is used for generating a PI syndrome according to the ECC block from the demodulator 2201. The PI syndrome memory 2209 is used for storing the PI syndrome from the on the fly PI syndrome generator 2207. The ECC decoder 2215 is used for performing an ECC operation according to the PI syndrome stored in the PI syndrome memory 2209 and PO syndrome stored in the PO syndrome memory 1809 to generate errata result. The EDC memory 2217 is used for buffering the EDC result. The EDC corrector 2219 is used for correcting the EDC result according to the errata result received from the ECC decoder 2215.

The operation of the error correction system 2200 is described as follows. The demodulated data from the demodulator 2203 is transmitted to the on the fly PI syndrome generator 2207, the on the fly EDC check device 2205 and the data buffer 2201, wherein the PI syndrome is stored in the PI syndrome memory 2209 and the EDC result is stored in the data buffer 2201. The following operations are performed if enough data for decoding is stored in the data buffer 2201. The EDC result stored in the data buffer 2201 is read and stored in the EDC memory 2217.

The ECC decoder 2215 performs an ECC operation with one direction according to the PI syndrome stored in the PI syndrome memory 2209, a syndrome correction circuit (not illustrated) in the ECC decoder 2215 updates the PI and PO syndrome in the PI syndrome memory 2209 and the PO syndrome memory 2213 correspondingly and simultaneously, and the EDC corrector 2219 updates the EDC result in the EDC memory 2217 correspondingly and simultaneously. The ECC block stored in the data buffer 2201 is read and the PO syndrome generator 2211 computes the PO syndrome, which is stored in the PO syndrome memory 2213. When the ECC operation with one direction is finished, an ECC operation with another direction is performed by directly reading a syndrome from the syndrome memories 2209 and 2211 instead of accessing the ECC block in the data buffer 2201 to re-compute syndromes. ECC operations of two directions continue repeatedly and alternately until the repeating numbers reach a predetermined value or no error data exists.

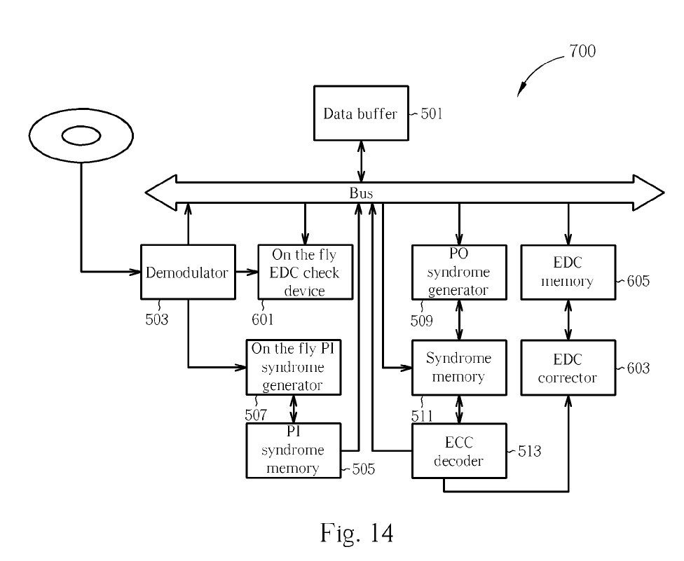

FIG. 14 is a block diagram illustrating an error correction system 700 according to a thirteenth embodiment of the present invention. As shown in FIG. 14, the error correction system 700 includes a data buffer 501, a demodulator 503, an on the fly EDC check device 601, an on the fly PI syndrome generator 507, a PI syndrome memory 505, a PO syndrome generator 509, a syndrome memory 511, an ECC decoder 513, an EDC memory 605 and an EDC corrector 603. The ECC decoder 513 is used for performing an ECC operation according to the PI syndrome stored in the PI syndrome memory 505 to generate errata result and PO syndrome stored in the PO syndrome memory 509. The EDC memory 605 is used for buffering the EDC result. The EDC corrector 603 is used for correcting the EDC result according to the errata result received from the ECC decoder 513.

The operation of the error correction system 700 is described as follows. The demodulated data from the demodulator 503 is transmitted to the on the fly PI syndrome generator 507, the on the fly EDC check device 601 and the data buffer 501, wherein the PI syndrome is stored in the PI syndrome memory 505 and the EDC result is stored in the data buffer 501. The following operations are performed if enough data for decoding is stored in the data buffer 501. The EDC result stored in the data buffer 501 is read and stored in the EDC memory 605. The ECC decoder 513 performs a ECC operation with one direction according to the PI syndrome stored in the data buffer 501. A syndrome correction circuit (not illustrated) in the ECC decoder 513 updates the PI and PO syndrome in the syndrome memory 511 correspondingly, and the EDC corrector 603 updates the EDC result in the EDC memory 605 correspondingly. The ECC block stored in the data buffer 501 is read and the PO syndrome generator 509 computes the PO syndrome, which is stored in the syndrome memory 511. When the ECC operation with one direction is finished, an ECC operation with another direction is performed by reading a syndrome from the syndrome memory 511 to re-compute syndromes. ECC operations of two directions continue repeatedly and alternately until the repeating numbers reach a predetermined value or no error data exists.

FIG. 15 is a block diagram illustrating an error correction system 2300 according to a fourteenth embodiment of the present invention. Compared with the error correction system 2200 shown in FIG. 13, the error correction system 2300 further has an on the fly PI ECC decoder 2301, and the on the fly PI syndrome generator 2207 is integrated to the on the fly PI ECC decoder 2301. Therefore the connections and the operations of the error correction systems 2200 and 2300 are different.

The operation of the error correction system 2300 shown in FIG. 15 is described as follows: The demodulated data from the demodulator 2203 is transmitted to the on the fly PI ECC decoder 2301, the on the fly EDC check device 2205 and the data buffer 2201, wherein the PI syndrome is stored in the PI syndrome memory 2209 and the EDC result is stored in the data buffer 2201.

The following operations are performed if enough data for decoding is stored in the data buffer 2201. The EDC result stored in the data buffer 2201 is read and stored in the EDC memory 2217, and the PO syndrome generator 2211 computes PO syndrome to be stored in the PO syndrome memory. ECC decoder 2215 performs an ECC operation with one direction according to the PO syndrome, a syndrome correction circuit in the ECC decoder 2215 updates the PO syndrome in the PO syndrome memory simultaneously, and EDC corrector 2219 updates EDC result in the EDC memory 2217 simultaneously.

Next, an ECC operation of next direction is performed by the ECC decoder 2215 according to the PI syndrome, a syndrome correction circuit in the ECC decoder 2215 updates the syndrome in the syndrome memory simultaneously, and EDC corrector 2219 updates EDC result in the EDC memory 2217 simultaneously.

Then a ECC operation with next direction is performed by reading a syndrome from the PI syndrome memory 2209 or the PO syndrome memory 2213 to re-compute syndromes. Two directions of ECC operations continue repeatedly and alternately until the repeating numbers reach a predetermined value or no error data exists.

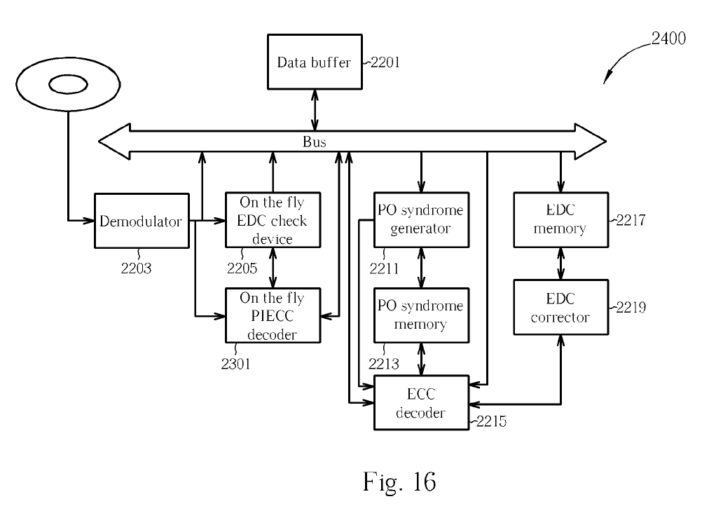

The PI syndrome memory 2209 shown in the error correction system 2300 can be integrated to the data buffer, as shown in FIG. 16, which is a block diagram illustrating an error correction system 2400 according to a fifteenth embodiment of the present invention. In the error correction system 2400, the PI syndrome from the on the fly PI ECC decoder 2301 is stored in the data buffer 2201 instead of the PI syndrome memory 2209. Since the operations of the error correction system 2400 can be easily obtained through the description of the error correction system 2300 and the structure of the error correction system 2400, they are omitted here for brevity.

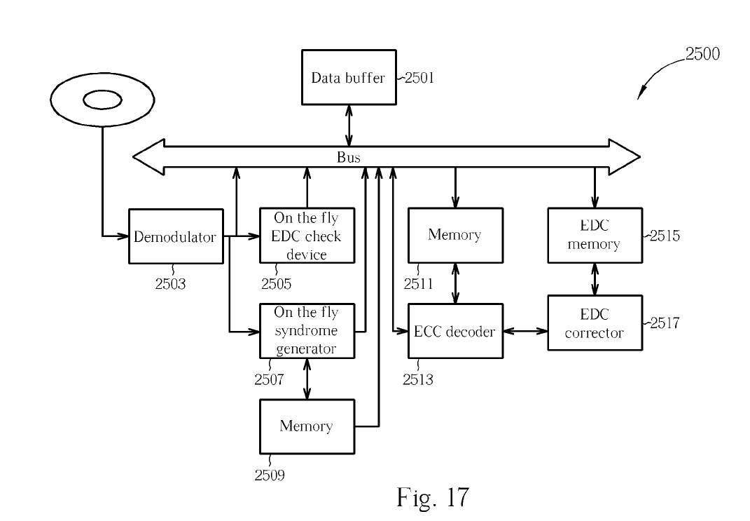

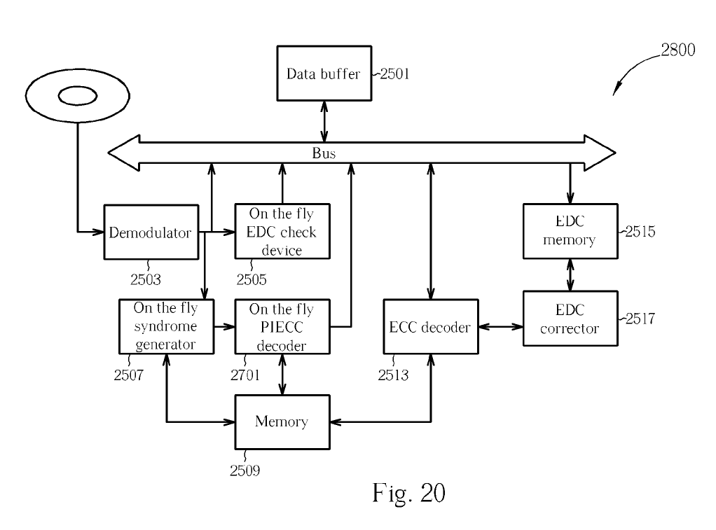

FIG. 17˜FIG. 20 are block diagrams illustrating other embodiments of the present invention; these embodiments all include an on the fly EDC check device, a syndrome generator and a syndrome memory located before a data buffer, and have the same elements located behind the data buffer.

FIG. 17 is a block diagram illustrating an error correction system 2500 according to a sixteenth embodiment of the present invention. As shown in FIG. 17, the error correction system 2500 includes a data buffer 2501, a demodulator 2503, an on the fly EDC check device 2505, a on the fly syndrome generator 2507, memories 2509 and 2511 memory 2511, an ECC decoder 2513, an EDC memory 2515, and an EDC corrector 2517. The demodulator 2503 is used for receiving and demodulating raw data from an optical disc to generate an ECC block that comprises data, PI parity, and PO parity. The data buffer 2501 is used for storing the ECC block. The on the fly syndrome generator 2507 is used for generating a syndrome according to the PI codeword or PO codeword of the ECC block directly from the demodulator 2501. The memory 2509 is used for storing the syndrome from the on the fly syndrome generator 2507. The memory 2511 is used for storing the syndrome from the data buffer 2501. The ECC decoder 2513 is used for performing a PI or PO ECC operation according to the syndrome buffered in the memory 2511 to generate PI or PO errata result. The EDC memory 2515 is used for buffering the EDC result from the data buffer 2501. The EDC corrector 2517 is used for correcting the EDC result according to the PI errata result or the PO errata result received from the ECC decoder 2517.

The operation of the error correction system 2500 is described as follows. The demodulated data from the demodulator 2503 is transmitted to the data buffer 2501, the on the fly EDC check device 2505 and the on the fly syndrome generator 2507. The syndrome result and the EDC result are stored in the data buffer 2501.

The following operations are performed if enough data for decoding is buffered in the data buffer 2501. The EDC result is read to the EDC memory 2515. The syndrome result is read to the memory 2511, and the ECC decoder 2513 performs a ECC operation with one direction, a syndrome correction circuit (not illustrated) in the ECC decoder 2513 updates the syndrome in the memory 2511 correspondingly and simultaneously, and the EDC corrector 2517 updates the EDC result in the EDC memory 2515 correspondingly and simultaneously. Such operation will be repeated for each row until all rows are corrected.

After all the rows are corrected, the ECC decoder 2513 performs a ECC operation of another direction according to PO syndrome result, a syndrome correction circuit (not illustrated) in the ECC decoder 2513 updates the syndrome in the memory 2511 correspondingly and simultaneously, and the EDC corrector 2517 updates the EDC result in the EDC memory 2515 correspondingly and simultaneously. Such operation will be repeated to each column until all the columns are corrected.

After all columns are corrected, an ECC operation of the next direction is performed by directly reading a syndrome from the memory 2511 instead of accessing the ECC block in the data buffer 2501 to re-compute syndromes. ECC operations of two directions continue repeatedly and alternately until the repeating numbers reach a predetermined value or no error data exists.

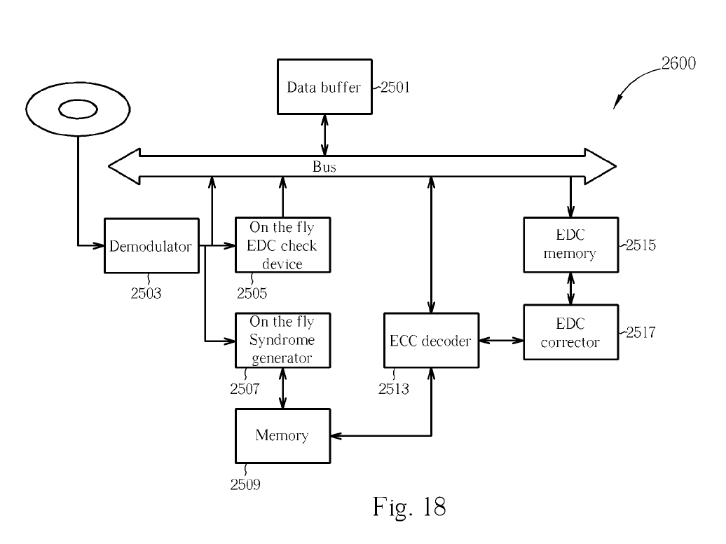

The syndrome result of the memory 2511 shown in the error correction system 2500 is not limited to be buffered into the data buffer 2501, as shown FIG. 18, thus the operation and the connections of the error correction systems 2500 and 2600 are different. FIG. 18 is a block diagram illustrating an error correction system 2600 according to a seventeenth embodiment of the present invention. The operations of the error correction system 2600 are described as follows: The demodulated data from the demodulator 2503 is transmitted to the data buffer 2501, the on the fly EDC check device 2505 and the on the fly syndrome generator 2507. The syndrome result is stored in the memory 2509, and the EDC result is stored in the data buffer 2501.

The following operations are performed if enough data for decoding is buffered in the data buffer 2501. The EDC result is read to the EDC memory 2515. The ECC decoder 2513 performs a ECC operation with one direction according to the syndrome stored in the memory 2509, a syndrome correction circuit (not illustrated) in the ECC decoder 2513 updates the syndrome in the memory 2509 correspondingly and simultaneously, and the EDC corrector 2517 updates the EDC result in the EDC memory 2515 correspondingly and simultaneously. Such operation will be repeated for each row until all rows are corrected.

After all the rows are corrected, the ECC decoder 2513 performs a ECC operation with another direction according to the PO syndrome result, a syndrome correction circuit (not illustrated) in the ECC decoder 2513 updates the syndrome in the memory 2511 correspondingly and simultaneously, and the EDC corrector 2517 updates the EDC result in the EDC memory 2515 correspondingly and simultaneously. Such operation will be repeated to each column until all the columns are corrected.

After all columns are corrected, an ECC operation of another direction is performed by directly reading syndromes from the memory 2511 instead of accessing the ECC block in the data buffer 2501 to re-compute syndromes. ECC operations of two directions continue repeatedly and alternately until the repeating numbers reach a predetermined value or no error data exists.

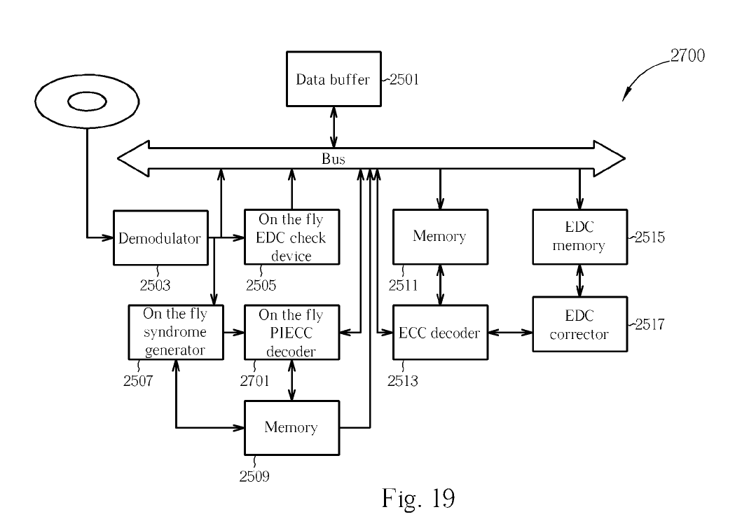

The error correction system 2500 can further comprise an on the fly PI ECC decoder 2701, as shown in FIG. 19. FIG. 19 is a block diagram illustrating an error correction system 2700 according to a eighteenth embodiment of the present invention, the operation of which is described as follows. The demodulated data from the demodulator 2503 is transmitted to the data buffer 2501, the on the fly EDC check device 2505 and the on the fly syndrome generator 2507.

The on the fly PI ECC decoder 2701 performs a PI ECC operation on the EDC block stored in the data buffer 2501 according to the syndrome from the on the fly syndrome generator 2507 to generate syndrome result and EDC result, which are stored in the data buffer 2501. Simultaneously with the PI ECC operation, a syndrome correction circuit (not illustrated) in the ECC decoder 2513 updates the syndrome in the memory 2511 correspondingly and the EDC corrector 2517 updates the EDC result in the data buffer 2501 correspondingly.

The following operations are performed if enough data for decoding is buffered in the data buffer 2501. The EDC result is read to the EDC memory 2515. The PO syndrome result is read to the memory 2511 The ECC decoder 2513 performs a ECC operation with one direction on the data stored in the data buffer 2501 according to the syndrome stored in the memory 2511, a syndrome correction circuit (not illustrated) in the ECC decoder 2513 updates the syndrome in the memory 2511 correspondingly and simultaneously, and the EDC corrector 2517 updates the EDC result in the EDC memory 2515 correspondingly and simultaneously.

Then PI syndrome result is read from the memory 2509 and the ECC decoder 2513 performs an ECC operation of another direction, a syndrome correction circuit (not illustrated) in the ECC decoder 2513 updates the syndrome in the memory 2511 correspondingly and simultaneously, and the EDC corrector 2517 updates the EDC result in the EDC memory 2515 correspondingly and simultaneously.

Thereafter, an ECC operation of another direction is performed by directly reading a syndrome from the memory 2511 instead of accessing the ECC block in the data buffer 2501 to re-compute syndromes. ECC operations of two operations continue repeatedly and alternately until the repeating numbers reach a predetermined value or no error data exists.

The syndrome result of the memory 2511 is not limited to be buffered into the data buffer 2501, as shown in FIG. 20, thus the operations and connections of the error correction systems 2700 and 2800 are different. FIG. 20 is a block diagram illustrating an error correction system 2800 according to an nineteenth embodiment of the present invention, the operation of which is described as follows. The demodulated data from the demodulator 2503 is transmitted to the data buffer 2501, the on the fly EDC check device 2505 and the on the fly syndrome generator 2507.

The on the fly PI ECC decoder 2701 performs a PI ECC operation according to the syndrome from the on the fly syndrome generator 2507, and updates the syndrome in the memory 2509. The syndrome result stored in the memory 2509 and the EDC result are stored in the data buffer 2501. Simultaneously with the PI ECC operation, a syndrome correction circuit (not illustrated) in the ECC decoder 2513 updates the syndrome in the memory 2509 correspondingly and the EDC corrector 2517 updates the EDC result in the EDC memory 2515 correspondingly.

The following operations are performed if enough data for decoding is buffered in the data buffer 2501. The EDC result is read to the EDC memory 2515. The ECC decoder 2513 performs an ECC operation with another direction on the data stored in the data buffer 2501 according to the syndrome result stored in the memory 2509, a syndrome correction circuit (not illustrated) in the ECC decoder 2513 updates the syndrome in the memory 2509 correspondingly and simultaneously, and the EDC corrector 2517 updates the EDC result in the EDC memory 2515 correspondingly and simultaneously.

Then PI syndrome result is read from the memory 2509 and the ECC decoder 2513 performs an ECC operation of another direction, a syndrome correction circuit (not illustrated) in the ECC decoder 2513 updates the syndrome in the memory 2511 correspondingly and simultaneously, and the EDC corrector 2517 updates the EDC result in the EDC memory 2515 correspondingly and simultaneously.

An ECC operation of the next direction is performed by directly reading a syndrome from the memory 2509 instead of accessing the ECC block in the data buffer 2501 to re-compute syndromes. ECC operations of two directions continue repeatedly and alternately until the repeating numbers reach a predetermined value or no error data exists.

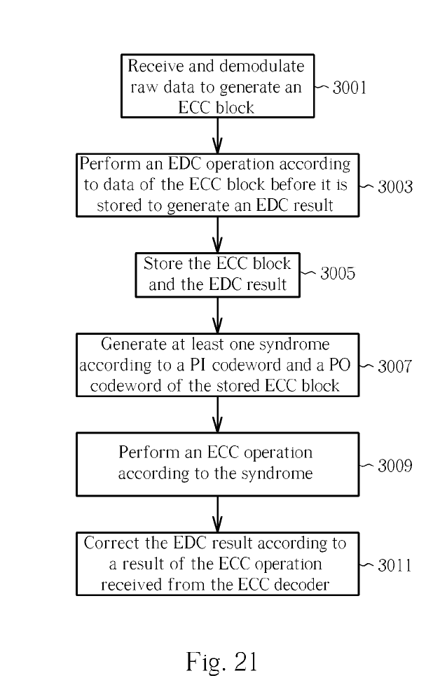

FIG. 21 illustrates an error correction method corresponding to the error correction system 1100 shown in FIG. 2. The method comprises:

### Step 3001

### Receive and demodulating raw data to generate an ECC block.

### Step 3003

### Perform an EDC operation according to data of the ECC block before it is stored to generate an EDC result.

### Step 3005

### Store the ECC block and the EDC result.

### Step 3007

### Generate at least one syndrome according to a PI codeword and a PO codeword of the stored ECC block.

### Step 3009

### Perform an ECC operation according to the syndrome.

### Step 3011

### Correct the EDC result according to an errata result of the ECC operation received from the ECC decoder.

ECC operations according to PI syndrome or PO syndrome will continue repeatedly and alternately until the repeating numbers reach a predetermined value or no error data exists.

If this method corresponds the error correction system 1200 shown in FIG. 3, it further comprises: Perform a PI ECC operation on the ECC block from the step 3001, thereby correcting error data and amending the EDC result according to an errata result of the PI ECC operation.

If this method corresponds the error correction system 1200 shown in FIG. 4, it further comprises: store a the ECC block from the step 3001, and perform a PI ECC operation on the stored the ECC block. Also, the step 3003 further performs the EDC operation on the stored the ECC block after the PI ECC operation to generate the EDC result.

Other detail characteristics are disclosed in the description of FIG. 2˜FIG. 4, thus it is omitted for brevity.

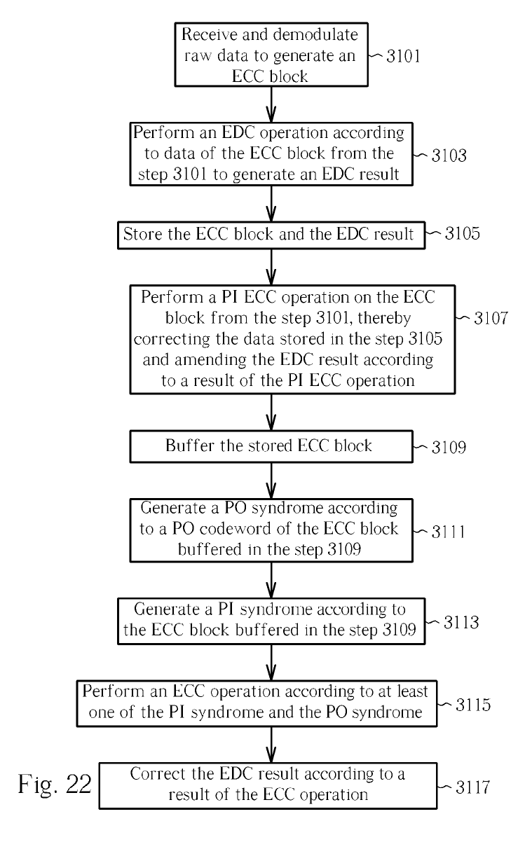

FIG. 22 illustrates an error correction method corresponding to the error correction system 1400 shown in FIG. 5. The method comprises:

### Step 3101

### Receive and demodulating raw data to generate an ECC block.

### Step 3103

### Perform an EDC operation according to data of the ECC block from the step 3101 to generate an EDC result.

### Step 3105

### Store the ECC block and the EDC result.

### Step 3107

### Perform a PI ECC operation on the ECC block from the step 3101, thereby correcting the data stored in the step 3105 and amending the EDC result according to a errata result of the PI ECC operation.

### Step 3109

### Buffer a part of the stored ECC block.

### Step 3111

### Generate a PO syndrome according to a PO codeword of the ECC block buffered in the step 3109.

### Step 3113

### Generate a PI syndrome according to the ECC block buffered in the step 3109.

### Step 3115

### Perform an ECC operation according to at least one of the PI syndrome and the PO syndrome.

### Step 3117

### Correct the EDC result according to a errata result of the ECC operation.

ECC operations according to PI syndrome or PO syndrome will continue repeatedly and alternately until the repeating numbers reach a predetermined value or no error data exists.

Other detail characteristics are disclosed in the description of FIG. 5, thus it is omitted for brevity.

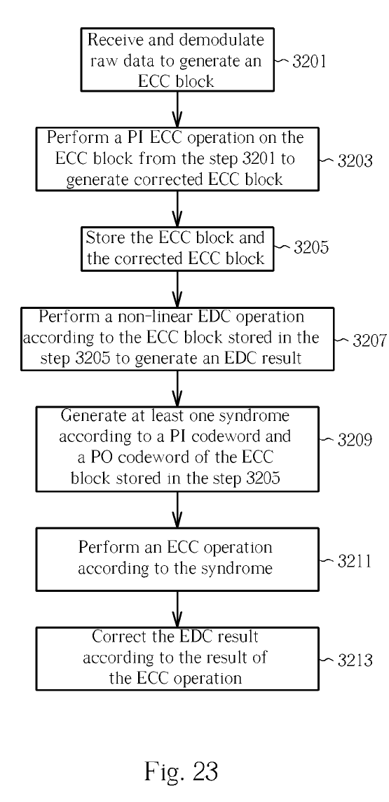

FIG. 23 illustrates a flow chart illustrating an error correction method corresponding to the error correction system 1500 shown in FIG. 6. The method comprises:

### Step 3201

### Receive and demodulate raw data to generate an ECC block.

### Step 3203

### Perform a PI ECC operation on the ECC block from the step 3201 to generate corrected ECC block.

### Step 3205

### Store the ECC block and the corrected ECC block.

### Step 3207

### Performing a non-linear EDC operation according to the ECC block stored in the step 3205 to generate an EDC result.

### Step 3209

### Generate at least one syndrome according to a PI codeword and a PO codeword of the ECC block stored in the step 3205.

### Step 3211

### Perform an ECC operation according to the syndrome

### Step 3213

### Correct the EDC result according to the result of the ECC operation The syndrome of this method comprises at least one of a PI syndrome and a PO syndrome.

ECC operations according to PI syndrome or PO syndrome will continue repeatedly and alternately until the repeating numbers reach a predetermined value or no error data exists.

If the method shown in FIG. 21 corresponds the error correction system 1600 shown in the FIG. 7, it further comprises: storing part of the ECC block from the step 3201. Other variation can be obtained by above-mentioned disclosure.

If the method shown in FIG. 21 corresponds the error correction system 2100 shown in the FIG. 12, the step 3209 generates the PO syndrome to be stored, the step 3203 generates the PI syndrome, and the PI syndrome and the PO syndrome are stored to different storage devices. Besides if the method shown in FIG. 21 corresponds the error correction system 2100 shown in the FIG. 12, the method further stores the PI syndrome generated by the step 3203 for the step 3011.

Other detail characteristics are disclosed in the description of FIG. 6, FIG. 7, FIG. 11 and FIG. 12, thus it is omitted for brevity.

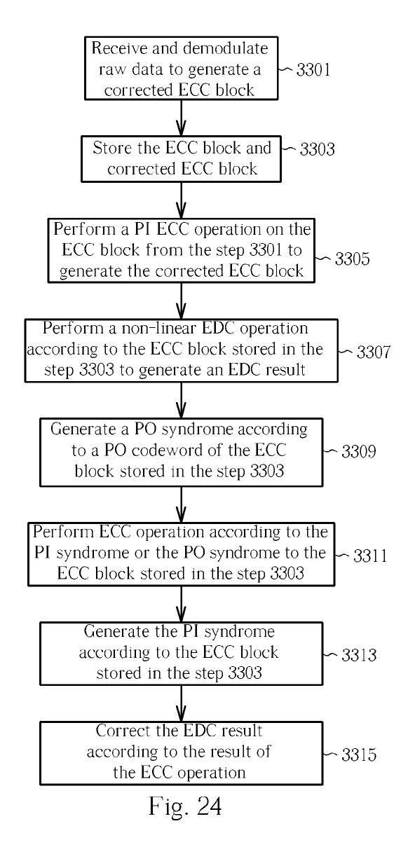

FIG. 24 illustrates a flow chart illustrating an error correction method corresponding to the error correction system 1700 shown in FIG. 8. The method comprises:

### Step 3301

### Receive and demodulating raw data to generate a corrected ECC block.

### Step 3303

### Store the ECC block and corrected ECC block.

### Step 3305

### Perform a PI ECC operation on the ECC block from the step 3301 to generate the corrected ECC block.

### Step 3307

### Perform a non-linear EDC operation according to the ECC block stored in the step 3303 to generate an EDC result.

### Step 3309

### Generate a PO syndrome according to a PO codeword of the ECC block stored in the step 3303.

### Step 3311

### Perform ECC operation according to the PI syndrome or the PO syndrome to the ECC block stored in the step 3303.

### Step 3313

### Generate the PI syndrome according to the ECC block stored in the step 3303.

### Step 3315

### Correct the EDC result according to the result of the ECC operation.

Other detail characteristics are disclosed in the description of FIG. 8, thus it is omitted for brevity.

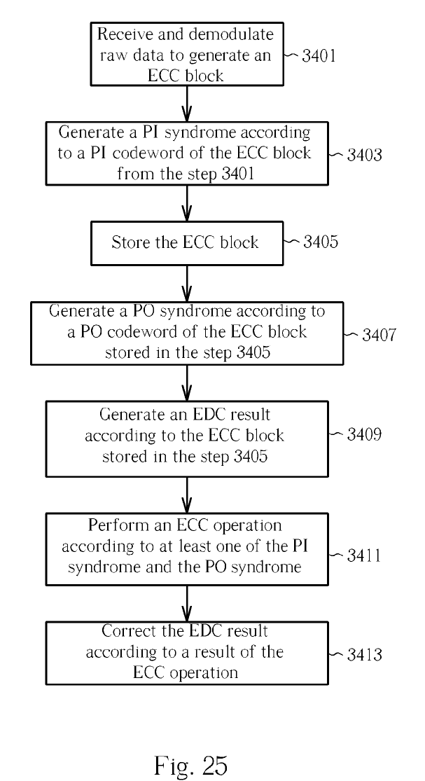

FIG. 25 illustrates a flow chart illustrating an error correction method corresponding to the error correction system 1800 and 1900 shown in FIG. 9˜FIG. 20. The method comprises:

### Step 3401

### Receive and demodulate raw data to generate an ECC block

### Step 3403

### Generate a PI syndrome according to a PI codeword of the ECC block from the step 3401.

### Step 3405

### Store the ECC block.

### Step 3407

### Generate a PO syndrome according to a PO codeword of the ECC block stored in the step 3405.

### Step 3409

### Generate an EDC result according to the ECC block stored in the step 3405.

### Step 3411

### Perform an ECC operation according to at least one of the PI syndrome and the PO syndrome.

### Step 3413

### Correct the EDC result according to a result of the ECC operation.

In this method, the syndrome comprises at least one of a PI syndrome and a PO syndrome.

ECC operations according to PI syndrome or PO syndrome will continue repeatedly and alternately until the repeating numbers reach a predetermined value or no error data exists.

If the method shown in FIG. 25 corresponds to the error correction systems shown in FIG. 13 and FIG. 14. The method further includes generating the PO syndrome according to the ECC block stored in the step 3405, and the step 3403 is used for generating the PI syndrome.

Besides, If the method shown in FIG. 25 corresponds to the error correction systems shown in FIG. 15 and FIG. 16, the step 3403 further performs a PI ECC operation.

Furthermore, if the method shown in FIG. 25 corresponds to the error correction systems shown in FIG. 17, it further comprises storing the syndrome and supplying the syndrome for the step 3409.

Also, if the method shown in FIG. 25 corresponds to the error correction systems shown in FIG. 19, further comprises storing the syndrome and supplying the syndrome for the step 3409.

Additionally, if the method shown in FIG. 25 corresponds to the error correction system shown in FIG. 20, it further comprises correcting the data of the ECC block and the EDC result stored in the step 3405, and correcting the stored syndrome.

It should be noted that the above-mentioned system operation orders are only given as examples and are not meant to limit the scope of the present invention. Persons skilled in the art can easily change the operation orders via the same systems to reach the same function, and this also falls within the scope of the present invention. Furthermore, the above mentioned raw data is from an optical disc, but this is only an example and is not a limitation of the present invention. The raw data can be obtained from any other source.

The above-mentioned systems have different structures and advantages. For example, the utilization of the syndrome memory and the syndrome correction circuit can decrease the bandwidth consumption of the data buffer. Also, the utilization of the EDC memory and the EDC corrector can decrease the bandwidth consumption of the data buffer. Moreover, the present invention can concurrently use the syndrome memory, the syndrome correction circuit, the EDC memory and the EDC corrector, and the PI, PO ECC to provide various kinds of error correction systems. Thus the present invention can be utilized to meet many different requirements.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An error correction system, comprising:
a demodulator for receiving and demodulating raw data to generate an ECC block;
an on the fly EDC check device for performing an EDC operation according to data of the ECC block from the demodulator to generate an EDC result;
a data buffer for storing the ECC block and the EDC result;
a syndrome generator for generating at least one syndrome according to a codeword of the ECC block stored in the data buffer;
an ECC decoder for performing an ECC operation according to the syndrome; and
an EDC corrector for correcting the EDC result according to a result of the ECC operation received from the ECC decoder;
wherein the syndrome comprises at least one of a PI syndrome and a PO syndrome, and the codeword comprises at least one of a PI codeword and a PO codeword,

2. The system of claim 1, further comprising a syndrome memory to store the syndrome.

3. The system of claim 1, further comprising an EDC memory to store the EDC result.

4. The system of claim 1, wherein the raw data is stored in an optical disc.

5. The system of claim 1, further comprising:
an on the fly PI ECC decoder for performing a PI ECC operation on the ECC block from the demodulator, thereby correcting error data in the data buffer and amending the EDC result according to a result of the PI ECC operation.

6. The system of claim 1, further comprising:
a memory device for storing a the ECC block from the demodulator; and
an on the fly PI ECC decoder for performing a PI ECC operation on the ECC block stored in the memory device;
wherein the on the fly EDC check device further performs the EDC operation on the ECC block after the PI ECC operation to generate the EDC result.

7. An error correction system, comprising:
a demodulator, for receiving and demodulating raw data to generate an ECC block;
an on the fly EDC check device for performing an EDC operation according to data of the ECC block from the demodulator to generate an EDC result;
a data buffer for storing the ECC block and the EDC result;
an on the fly PI ECC decoder for performing a PI ECC operation on the ECC block from the demodulator, thereby correcting the ECC block in the data buffer and amending the EDC result according to a result of the PI ECC operation;
a memory device for storing a the ECC block from the data buffer;
a PO syndrome generator for generating a PO syndrome according to a PO codeword of the ECC block stored in the memory device;
a PI syndrome generator for generating a PI syndrome according to (a PI codeword of the ECC block stored in the memory device;
an ECC decoder for performing an ECC operation according to at least one of the PI syndrome and the PO syndrome; and
an EDC corrector for correcting the EDC result according to a result of the ECC operation.

8. The system of claim 7, further comprising a PI syndrome memory to store the PI syndrome.

9. The system of claim 7, further comprising an EDC memory to store the EDC result.

10. The system of claim 7, wherein the raw data is stored in an optical disc.

11. The system of claim 7, wherein the memory device is integrated into the data buffer.

12. An error correction method, comprising:
(a) receiving and demodulating raw data to generate an ECC block;
(b) performing an EDC operation according to data of the ECC block to generate an EDC result;
(c) storing the ECC block and the EDC result;
(d) generating at least one syndrome according to a codeword of the stored ECC block;
(e) performing an ECC operation according to the syndrome; and
(f) correcting the EDC result according to a result of the ECC operation;
wherein the syndrome comprises at least one of a PI syndrome and a PO syndrome, and the codeword comprises at least one of a PI codeword and a PO codeword,

13. The method of claim 12, further comprising storing the syndrome in the step (d).

14. The method of claim 12, further comprising storing the EDC result in the step (b).

15. The method of claim 12, wherein the raw data is stored in an optical disc.

16. The method of claim 12, further comprising:
performing a PI ECC operation on the ECC block from the step (a), thereby correcting error data and amending the EDC result according to a result of the PI ECC operation.

17. The system of claim 12, further comprising:
(g) storing a the ECC block from the step (a); and
(h) performing a PI ECC operation on the ECC block stored in the step (g);
wherein the step (h) further performs the EDC operation on the ECC block stored in the step (g) after the PI ECC operation to generate the EDC result.

18. An error correction method, comprising:
(a) receiving and demodulating raw data to generate an ECC block (b) performing an EDC operation according to data of the ECC block to generate an EDC result;
(c) storing the ECC block and the EDC result;
(d) performing a PI ECC operation on the ECC block, thereby correcting the ECC block and amending the EDC result according to a result of the PI ECC operation;
(e) storing a part of the stored ECC block;
(f) generating a PO syndrome according to a PO codeword of the ECC block buffered;
(g) generating a PI syndrome according to a PI codeword of the ECC block;
(h) performing an ECC operation according to at least one of the PI syndrome and the PO syndrome; and
(i) correcting the EDC result according to a result of the ECC operation.

19. The method of claim 18, further comprising storing the EDC result in the step (b).

20. The method of claim 18, wherein the raw data is stored in an optical disc.
